(19) United States
(12) Patent Application Publication
(10) Pub. No.: US 2025/0136434 A1
(43) Pub. Date: May 1, 2025

(54) MEMS SWITCH AND ELECTRONIC DEVICE

(71) Applicants: Beijing BOE Technology Development Co., Ltd., Beijing (CN); BOE Technology Group Co., Ltd., Beijing (CN)

(72) Inventors: Yingli SHI, Beijing (CN); Yanzhao LI, Beijing (CN)

(21) Appl. No.: 18/689,528

(22) PCT Filed: Feb. 16, 2023
(86) PCT No.: PCT/CN2023/076497

§ 371 Date: Mar. 6, 2024

(51) Int. Cl. B81B 3/00

(52) U.S. Cl. CPC B81B 3/0086; B81B 2201/018; B81B 2203/0109; B81B 2203/0118; B81B 2203/0127; B81B 2203/04

(57) ABSTRACT

Embodiments of the present disclosure provide an MEMS switch and an electronic device. The MEMS switch includes: a base substrate; an electrode structure on the base substrate, including a first ground electrode, a signal transmission line, a second ground electrode, a first drive electrode and a third ground electrode which are sequentially arranged on the base substrate at intervals; and a metal beam stretching over the electrode structure, where a first end of the metal beam is electrically connected to the third ground electrode, an orthographic projection of a second end of the metal beam on the base substrate is within an orthographic projection of the signal transmission line on the base substrate, and an orthographic projection of the metal beam on the base substrate is overlapped with an orthographic projection of the first drive electrode on the base substrate.

### TECHNICAL FIELD

The present disclosure relates to the technical field of RF MEMS, and particularly relates to an MEMS switch and an electronic device.

### BACKGROUND

The radio frequency (RF) switch designed and manufactured by the micro electro-mechanical system (MEMS) technology has the unique advantages of low insertion loss, low electric power consumption and the like. As one of the most basic elements of electronic circuit systems such as wireless communication and the like, the RF MEMS switch is widely applied to radar detection, wireless communication and the like. The new generation of information technology, which takes miniaturization and high functional density as the development direction, calls for a new generation of high-performance components. Compared with a conventional switch composed of an FET or PIN diode, the RF MEMS switch has the advantages of low insertion loss, low electric power consumption, small transmission signal distortion, and the like.

### SUMMARY

Embodiments of the present disclosure provide an MEMS switch and an electronic device, which specifically adopt the following technical solutions:

An embodiment of the present disclosure provides an MEMS switch, including:
a base substrate;
an electrode structure on the base substrate, including a first ground electrode, a signal transmission line, a second ground electrode, a first drive electrode and a third ground electrode which are sequentially arranged on the base substrate at intervals; and
a metal beam stretching over the electrode structure, wherein a first end of the metal beam is electrically connected to the third ground electrode, an orthographic projection of a second end of the metal beam on the base substrate is within an orthographic projection of the signal transmission line on the base substrate, and an orthographic projection of the metal beam on the base substrate is overlapped with an orthographic projection of the first drive electrode on the base substrate.

In a possible implementation, in the MEMS switch provided in the embodiment of the present disclosure, the second ground electrode and the third ground electrode form an integral structure, and the second ground electrode and the third ground electrode form a first hollowed-out region in which the first drive electrode is located.

In a possible implementation, in the MEMS switch provided in the embodiment of the present disclosure, the first drive electrode has the same shape as the first hollowed-out region, and the orthographic projection of the first drive electrode on the base substrate has an area smaller than an orthographic projection of the first hollowed-out region on the base substrate.

In a possible implementation, in the MEMS switch provided in the embodiment of the present disclosure, the first drive electrode is a continuously bent structure.

In a possible implementation, in the MEMS switch provided in the embodiment of the present disclosure, the first drive electrode includes: a first portion extending in a first direction, a second portion extending in a second direction, and a third portion extending in the first direction; and one end of the first portion is electrically connected to one end of the second portion, and the other end of the second portion is electrically connected to one end of the third portion; wherein the first direction is an extending direction of the signal transmission line, and the second direction is perpendicular to the first direction.

In a possible implementation, in the MEMS switch provided in the embodiment of the present disclosure, the first drive electrode has a substantially “ [symbol] ” shape.

In a possible implementation, in the MEMS switch provided in the embodiment of the present disclosure, the orthographic projection of the metal beam on the base substrate is overlapped with an orthographic projection of the first portion on the base substrate.

In a possible implementation, the MEMS switch provided in the embodiments of the present disclosure further includes a first dielectric layer on a side of the first drive electrode away from the base substrate, wherein an overlap region of the orthographic projections of the metal beam and the first drive electrode on the base substrate is a first overlap region, and an orthographic projection of the first dielectric layer on the base substrate has an area greater than an area of an orthographic projection of the first overlap region on the base substrate.

In a possible implementation, the MEMS switch provided in the embodiments of the present disclosure further includes a second dielectric layer on a side of the signal transmission line away from the base substrate, wherein the orthographic projections of the metal beam and the signal transmission line on the base substrate have a second overlap region, and an orthographic projection of the second dielectric layer on the base substrate has an area greater than an area of an orthographic projection of the second overlap region on the base substrate.

In a possible implementation, in the MEMS switch provided in the embodiment of the present disclosure, the metal beam is shaped as a straight structure, or an arc that is convex to a side away from the base substrate.

In a possible implementation, in the MEMS switch provided in the embodiment of the present disclosure, a first recess that is recessed to the first drive electrode is provided at a position of the metal beam facing first drive electrode.

In a possible implementation, in the MEMS switch provided in the embodiment of the present disclosure, a bottom surface of the first recess is planar or curved.

In a possible implementation, in the MEMS switch provided in the embodiment of the present disclosure, a position of the metal beam facing first drive electrode has a width greater than other positions of the metal beam.

In a possible implementation, the MEMS switch provided in the embodiments of the present disclosure further includes: a fourth ground electrode on a side of the first ground electrode away from the second ground electrode, and a second drive electrode between the first ground electrode and the fourth ground electrode; wherein a second end of the metal beam is electrically connected to the fourth ground electrode, the orthographic projection of the metal beam on the base substrate is overlapped with an orthographic projection of the second drive electrode on the base substrate.

In a possible implementation, in the MEMS switch provided in the embodiment of the present disclosure, the first ground electrode and the fourth ground electrode form an integral structure, and the first ground electrode and the fourth ground electrode form a second hollowed-out region in which the second drive electrode is located.

In a possible implementation, in the MEMS switch provided in the embodiment of the present disclosure, the second drive electrode has the same shape as the second hollowed-out region, and the orthographic projection of the second drive electrode on the base substrate has an area smaller than an area of an orthographic projection of the second hollowed-out region on the base substrate.

In a possible implementation, in the MEMS switch provided in the embodiment of the present disclosure, the second drive electrode and the first drive electrode are symmetrical about the signal transmission line.

In a possible implementation, the MEMS switch provided in the embodiments of the present disclosure further includes a third dielectric layer on a side of the second drive electrode away from the base substrate, wherein an overlap region of the orthographic projections of the metal beam and the second drive electrode on the base substrate is a third overlap region, and an orthographic projection of the third dielectric layer on the base substrate has an area greater than an area of an orthographic projection of the third overlap region on the base substrate.

In a possible implementation, in the MEMS switch provided in the embodiment of the present disclosure, a second recess that is recessed to the second drive electrode is provided at a position of the metal beam facing the second drive electrode.

In a possible implementation, in the MEMS switch provided in the embodiment of the present disclosure, a bottom surface of the second recess is planar or curved.

In a possible implementation, in the MEMS switch provided in the embodiment of the present disclosure, a position of the metal beam facing the second drive electrode has a width greater than other positions of the metal beam.

In a possible implementation, in the MEMS switch provided in the embodiment of the present disclosure, the metal beam is made of a material including Au, Ag, Cu, or Al.

Accordingly, an embodiment of the present disclosure further provides an electronic device, including the MEMS switch provided in the above embodiment of the present disclosure.

### BRIEF DESCRIPTION OF DRAWINGS

FIGS. 1 to 6 are schematic structural diagrams of an MEMS switch according to the existing art;

FIGS. 7 to 9 are schematic structural diagrams of an MEMS switch according to an embodiment of the present disclosure;

FIG. 10 is a simulation diagram of insertion loss simulation for the RF MEMS switches of different structural designs shown in FIGS. 1 and 4;

FIG. 11 is a schematic diagram showing distribution of an electrostatic field for the MEMS switch in FIG. 4;

FIG. 12 is a schematic diagram showing deformation of a cantilever membrane beam under the driving of the electrostatic field in FIG. 11;

FIG. 13 is a schematic diagram showing distribution of an electrostatic field for the MEMS switch in FIG. 7;

FIG. 14 is a schematic diagram showing deformation of a cantilever membrane beam driven by the electrostatic field in FIG. 13; and

FIGS. 15 to 23 are schematic structural diagrams of several MEMS switches according to embodiments of the present disclosure.

### DETAIL DESCRIPTION OF EMBODIMENTS

To make the objects, technical solutions and advantages of the embodiments of the present disclosure more apparent, the technical solutions according to the embodiments of the present disclosure will be clearly and completely described below with reference to the drawings of the embodiments of the present disclosure. Apparently, the described embodiments are some, but not all, of the embodiments of the present disclosure. Further, the embodiments of the present disclosure and features thereof may be combined with each other as long as they are not contradictory. All other embodiments obtained by those skilled in the art based on the embodiments of the present disclosure described herein without paying any creative effort shall be included in the protection scope of the present disclosure.

Unless otherwise defined, technical or scientific terms used in the present disclosure are intended to have general meanings as understood by those skilled in the art to which the present disclosure belongs. As used herein, the word “include” or “comprise” or the like means that the element or item preceding the word includes elements or items that appear after the word or equivalents thereof, but does not exclude other elements or items. The terms “connected” or “coupled” and the like are not restricted to physical or mechanical connections, but may include electrical connections, whether direct or indirect. The words “inner”, “outer”, “upper”, “lower”, and the like are merely used to indicate a relative positional relationship, and when an absolute position of the described object is changed, the relative positional relationship may be changed accordingly.

It should be noted that the sizes and shapes of various components in the drawings are not to scale, but are merely intended to schematically illustrate the present disclosure. The same or similar reference signs refer to the same or similar elements or elements with the same or similar functions throughout the drawings.

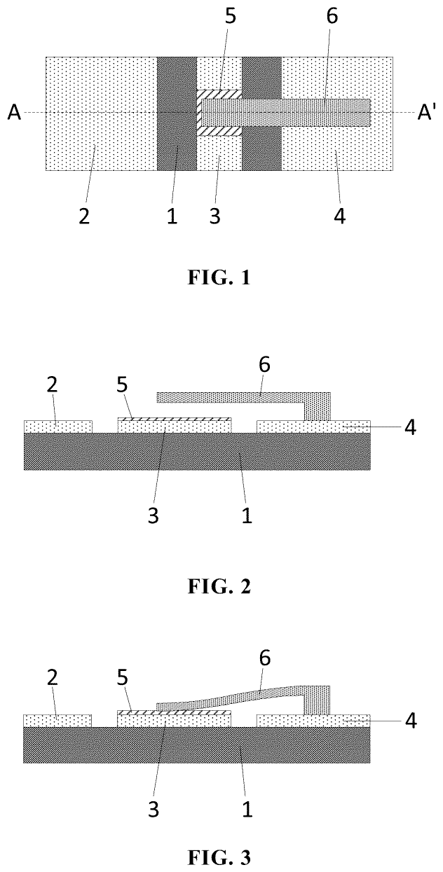

Common structures for MEMS switches include a beam membrane bridge structure with double end fixed and a cantilever beam structure. Taking the cantilever beam structure as an example, a common capacitive RF MEMS switch structure is shown in FIGS. 1 to 3, where FIG. 1 is a top view of a cantilever beam structure switch, and FIG. 2 is a side sectional view taken along AA′ in FIG. 1. The MEMS switch includes: a base substrate 1; a first ground electrode 2, a signal transmission line 3, and a second ground electrode 4 on the base substrate 1; a dielectric layer 5 on a side of the signal transmission line 3 away from the base substrate 1; and a cantilever membrane beam 6 electrically connected to the second ground electrode 4 and stretching above the signal transmission line 3. The first ground electrode 2, the signal transmission line 3 and the second ground electrode 4 form a coplanar waveguide (CPW) structure of “ground-signal-ground”. A drive voltage is applied to the cantilever membrane beam 6 to control a driving state (which may be on or off before operation) of the switch, and thereby control a radio frequency signal on the CPW structure. FIG. 2 shows the switch in an on state under the driving of a direct-current bias voltage, and FIG. 3 shows the switch in an off state.

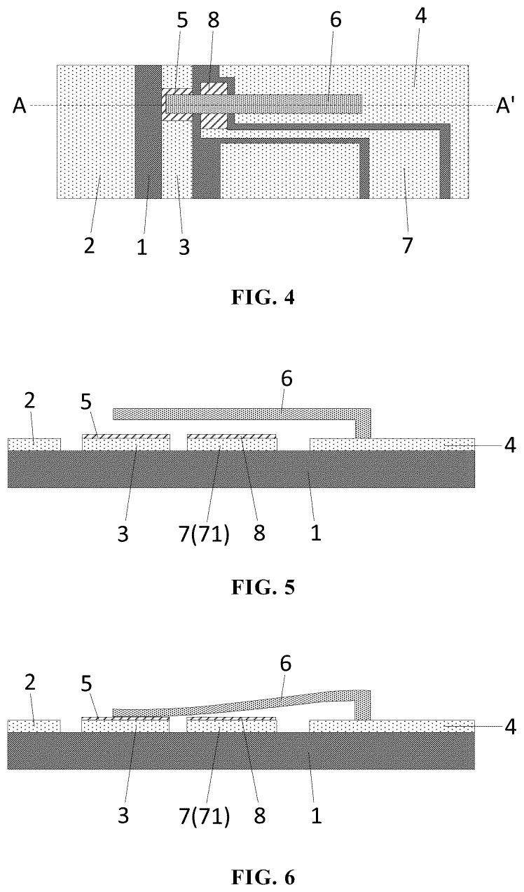

Since the signal transmission line 3 in the MEMS switch shown in FIGS. 1 to 3 is loaded with a direct current bias voltage and a radio frequency signal at the same time, there may be crosstalk between the direct current bias voltage and the radio frequency signal, thereby affecting performance of the RF MEMS switch. Therefore, in the existing art, an RF MEMS switch design with a direct current bias line separated from a signal transmission line is proposed. As shown in FIGS. 4 to 6, FIG. 4 is a top view of a cantilever beam structure switch, FIG. 5 is a side sectional view taken along AA′ in FIG. 4, FIG. 5 shows the switch an on state under the driving of a direct-current bias voltage, and FIG. 6 shows the switch in an off state. In the MEMS switch shown in FIGS. 4 to 6, a direct current bias line 7 (drive electrode) is designed to be separated from the signal transmission line 3, and a dielectric layer 8 is provided on a side of the direct current bias line 7 away from the base substrate 1, so that the crosstalk problem between the direct current bias voltage and the radio frequency signal is eliminated while the cantilever membrane beam 6 can be normally driven. However, due to the structural design in FIGS. 4 to 6, a direct current bias voltage driving end 71 of the direct current bias line 7 is located between the signal transmission line 3 and the second ground electrode 4, which destroys the integrity of the “ground-signal-ground” CPW structure in the RF MEMS switch, and may cause a significantly increased insertion loss and degrade the radio frequency performance of the switch device. As shown in FIG. 10, FIG. 10 shows insertion loss simulation for the RF MEMS switches of different structural designs shown in FIGS. 1 and 4 based on a finite element method. It can be seen that the RF MEMS switch with no separated drive electrode shown in FIG. 1 has an insertion loss of about −2 dB@17.7 GHZ, while the RF MEMS switch with a drive electrode between the signal transmission line and the ground electrode shown in FIG. 4 has an insertion loss of about −9.5 dB@17.7 GHZ. Therefore, although the structure shown in FIG. 4 can achieve decoupling of the drive electrode and the signal transmission line to prevent crosstalk, the radio frequency performance of the switch is greatly degraded.

In summary, how to implement separation of the direct current bias line and the signal transmission line while maintaining the integrity of the CPW structure in the RF MEMS switch has become an urgent technical problem to be solved by those skilled in the art.

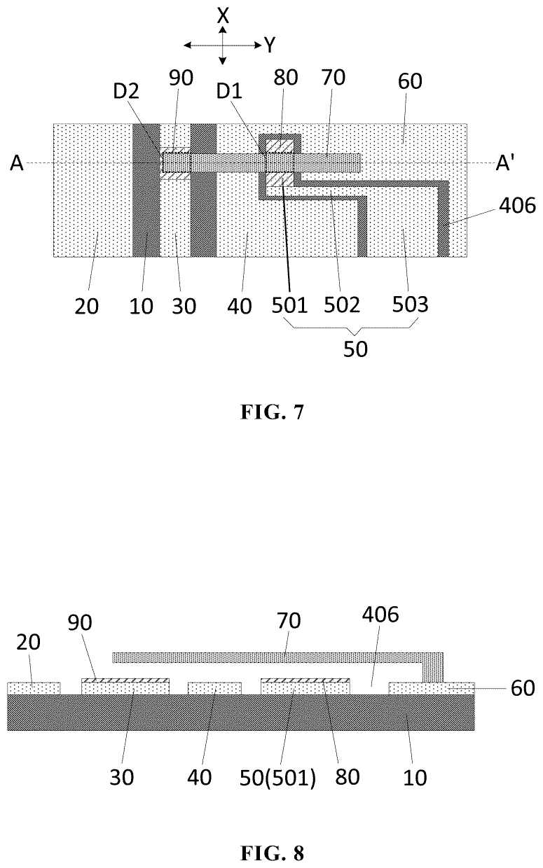

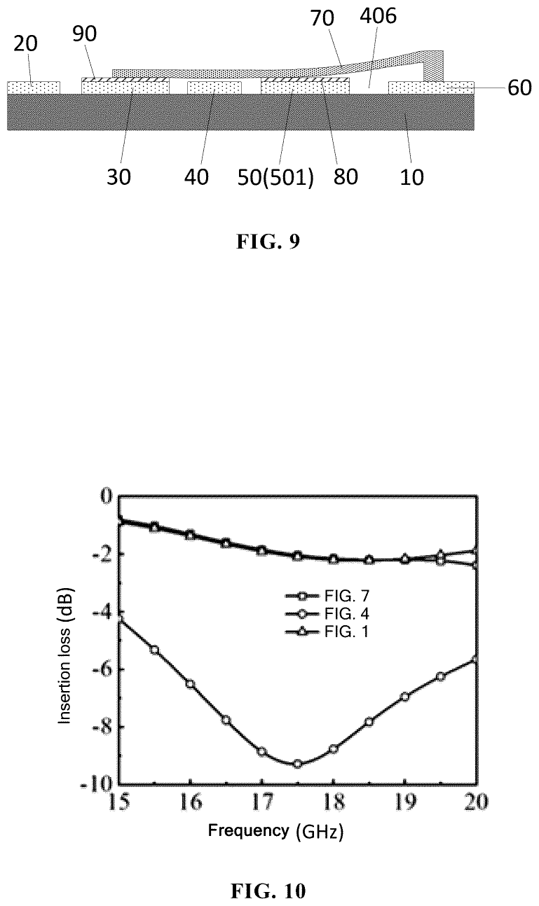

In view of this, to solve the above technical problem, an embodiment of the present disclosure provides an MEMS switch as shown in FIGS. 7 to 9. FIG. 7 is a top view of the MEMS switch, FIG. 8 is a side sectional view taken along AA′ in FIG. 7, FIG. 8 shows the switch an on state under the driving of a direct-current bias voltage, and FIG. 9 shows the switch in an off state. The MEMS switch includes:
a base substrate 10 which, optionally, may be a rigid base substrate such as a silicon or glass substrate, or may be a bendable flexible substrate such as LCP, PI, COP, or the like;
an electrode structure on the base substrate 10, including a first ground electrode 20, a signal transmission line 30, a second ground electrode 40, a first drive electrode 50 and a third ground electrode 60 which are sequentially arranged on the base substrate 10 at intervals; and
a metal beam 70 stretching over the electrode structure, where a first end of the metal beam 70 is electrically connected to the third ground electrode 60, an orthographic projection of a second end of the metal beam 70 on the base substrate 10 is located within an orthographic projection of the signal transmission line 30 on the base substrate 10, and an orthographic projection of the metal beam 70 on the base substrate 10 is overlapped with an orthographic projection of the first drive electrode 50 on the base substrate 10.

According to the MEMS switch provided in the embodiment of the present disclosure, the electrode structure is configured to include a first ground electrode, a signal transmission line, a second ground electrode, a first drive electrode and a third ground electrode which are sequentially arranged at intervals, where the first ground electrode, the signal transmission line and the second ground electrode forma coplanar waveguide (CPW) structure of the MEMS switch, and the signal transmission line for transmitting radio frequency and microwave signals is separated from the first drive electrode for loading a direct current bias voltage, so that the structural integrity of the “ground-signal-ground” CPW structure in the RF MEMS switch is guaranteed while the decoupling of the signal transmission line and the first drive electrode is implemented. To verify the radio frequency performance of the MEMS switch provided in the embodiment of the present disclosure, FIG. 10 further shows insertion loss simulation for the MEMS switch shown in FIG. 7 based on a finite element method. As can be seen from the finite element simulation result in FIG. 10, the MEMS switch of the present disclosure with a first drive electrode separated from a signal transmission line shown in FIG. 7 has an insertion loss of about −2 dB@17.7 GHZ, which is equivalent to the insertion loss of the MEMS switch with no separated drive electrode shown in FIG. 1, thereby proving the effectiveness of the MEMS structure design proposed in the present disclosure. Therefore, the MEMS switch provided in the embodiments of the present disclosure can not only implementing decoupling of the first drive electrode and the signal transmission line to prevent the problem of crosstalk, but also ensure the radio frequency performance of the MEMS switch.

In specific implementations, in the MEMS switch provided in the embodiment of the present disclosure, as shown in FIGS. 7 to 9, the second ground electrode 40 and the third ground electrode 60 may form an integral structure, and the second ground electrode 40 and the third ground electrode 60 may form a first hollowed-out region 406 in which the first drive electrode 50 is located. Specifically, the second ground electrode 40, the third ground electrode 60, and the first hollowed-out region 406 may be structures formed by patterning the second ground electrode 4 in FIG. 1 in the existing art. In other words, in the existing art, a first hollowed-out region is formed in the second ground electrode 4 in FIG. 1, in which the first drive electrode 50 is provided, so that the signal transmission line 30 is isolated from the first drive electrode 50 based on the original ground electrode of the MEMS switch without too many additional manufacturing processes, thereby simplifying the process.

Apparently, in practical implementations, the second ground electrode 40 and the third ground electrode 60 may be provided as two separate ground electrodes. For example, the third ground electrode 60 may be equivalent to the second ground electrode 4 in FIG. 5, and FIG. 7 of the present disclosure may be equivalent to adding the second ground electrode 40 between the signal transmission line 3 and the direct current bias line 7 in FIG. 5, thereby ensuring the structural integrity of the “ground-signal-ground” CPW structure while implementing decoupling of the first drive electrode 50 and the signal transmission line 30 to prevent the problem of crosstalk.

In specific implementations, in the MEMS switch provided in the embodiment of the present disclosure, as shown in FIGS. 7 to 9, the first drive electrode 50 has the same (substantially the same) shape as the first hollowed-out region 406, and the orthographic projection of the first drive electrode 50 on the base substrate 10 has an area smaller than an orthographic projection of the first hollowed-out region 406 on the base substrate 10. In this manner, it is ensured that the first drive electrode 50 is insulated from the second ground electrode 40 and the third ground electrode 60.

In specific implementations, in the MEMS switch provided in the embodiment of the present disclosure, as shown in FIG. 7, the first drive electrode 50 may be a continuously bent structure. Apparently, the present disclosure is not limited thereto. For example, the first drive electrode 50 may also be a strip-shaped electrode, a U-shaped electrode, or the like, and the first drive electrode 50 being a continuously bent structure is taken as an example for illustration in the embodiments of the present disclosure.

In specific implementations, in the MEMS switch provided in the embodiment of the present disclosure, as shown in FIG. 7, the first drive electrode 50 includes: a first portion 501 extending in a first direction X, a second portion 502 extending in a second direction Y, and a third portion 503 extending in the first direction X; and one end of the first portion 501 is electrically connected to one end of the second portion 502, and the other end of the second portion 502 is electrically connected to one end of the third portion 503; where the first direction X is an extending direction of the signal transmission line, and the second direction Y is perpendicular to the first direction X. Optionally, the first drive electrode 50 has a substantially “ [symbol] ” shape. Apparently, in practical implementations, the shape of the first drive electrode 50 is not limited to the structure shown in FIG. 7. That is, the shape of the first hollowed-out region 406 is not limited to the structure shown in FIG. 7, as long as a complete CPW structure can be guaranteed and a separate design of the first drive electrode 50 and the signal transmission line 30 can be achieved.

In specific implementations, in the MEMS switch provided in the embodiment of the present disclosure, as shown in FIGS. 7 to 9, the orthographic projection of the metal beam 70 on the base substrate 10 is overlapped with an orthographic projection of the first portion 501 on the base substrate 10. In this manner, the first portion 501 serves as a direct current bias voltage driving end, and the third portion 503 serves as a bias voltage applying pad.

In specific implementations, as shown in FIGS. 7 to 9, the MEMS switch provided in the embodiments of the present disclosure further includes a first dielectric layer 80 on a side of the first drive electrode 50 away from the base substrate 10. An overlap region of the orthographic projections of the metal beam 70 and the first drive electrode 50 on the base substrate 10 is a first overlap region D1, and an orthographic projection of the first dielectric layer 80 on the base substrate 10 has an area greater than an orthographic projection of the first overlap region D1 on the base substrate 10. This prevents short circuit of the metal beam 70 and the first drive electrode 50 when the MEMS device is in the off state, which may affect the performance of the switch.

In specific implementations, as shown in FIGS. 7 to 9, the MEMS switch provided in the embodiments of the present disclosure further includes a second dielectric layer 90 on a side of the signal transmission line 30 away from the base substrate 10. The orthographic projections of the metal beam 70 and the signal transmission line 30 on the base substrate 10 have a second overlap region D2, and an orthographic projection of the second dielectric layer 90 on the base substrate 10 has an area greater than an orthographic projection of the second overlap region D2 on the base substrate 10. The MEMS switch shown in FIG. 7 thus formed is a capacitive switch.

Specifically, as shown in FIGS. 7 and 8, when positive and negative voltages are applied to the first drive electrode 50 and the metal beam 70, the metal beam 70 approaches the signal transmission line 30 (as shown in FIG. 9), and in a non-pressurized state (i.e., no voltage is applied to the first drive electrode 50 or the metal beam 70), the metal beam 70 keeps away from the signal transmission line 30, that is, the metal beam 70 does not approach the signal transmission line 30 (as shown in FIG. 8). Therefore, the MEMS switch provided in the embodiments of the present disclosure can enable the metal beam 70 to approach the signal transmission line 30 when a certain voltage is applied, and enable the metal beam 70 to keep away from the signal transmission line 30 when no voltage is applied, thereby implementing functions similar to a switch or the like.

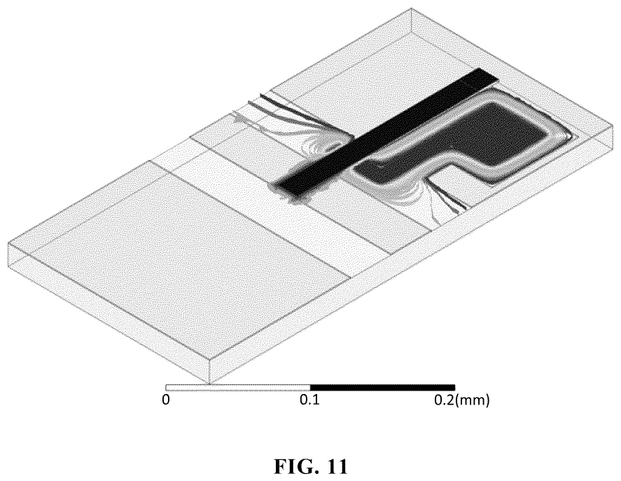

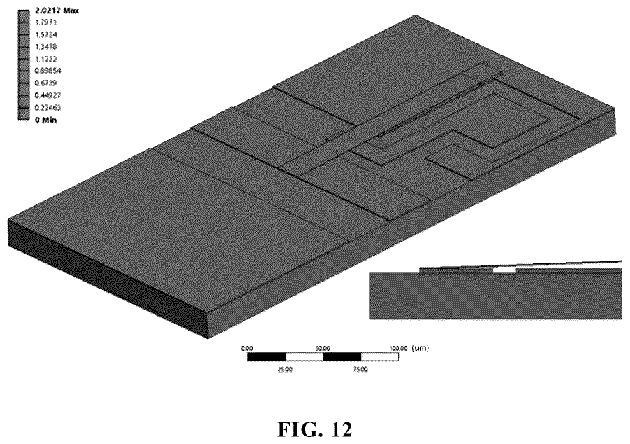

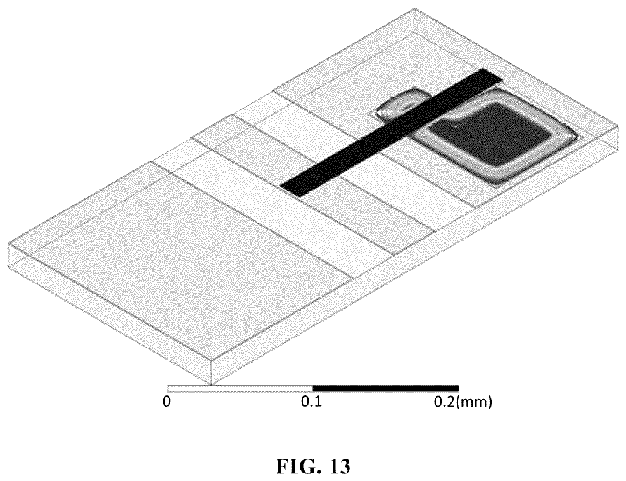

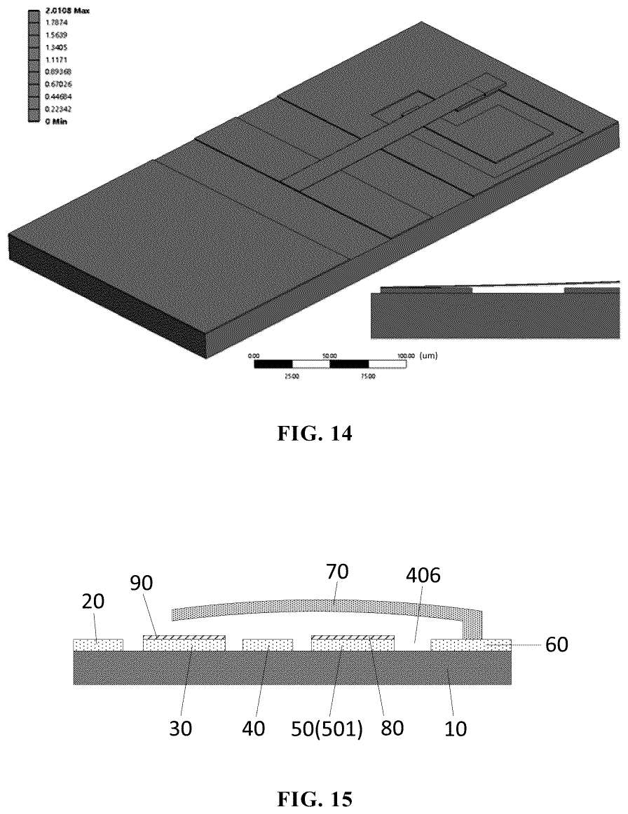

To further verify the feasibility of the MEMS switch shown in FIG. 7 provided in the embodiment of the present disclosure, a driving effect diagram of the MEMS switch shown in FIG. 7 provided in the embodiment of the present disclosure is simulated by taking the MEMS switch shown in FIG. 4 as a comparison. Specifically, for the MEMS switch shown in FIG. 4, positive and negative voltages are respectively applied on the drive electrode 7 and the cantilever membrane beam 6, resulting in an electrostatic field distributed as shown in FIG. 11, and under the driving of the electrostatic field, the driven deformation of the cantilever membrane beam 6 in the MEMS switch shown in FIG. 4 is as shown in FIG. 12. For the MEMS switch of the present disclosure shown in FIG. 7, positive and negative voltages are respectively applied on the first drive electrode 50 and the metal beam 70, resulting in an electrostatic field distributed as shown in FIG. 13, and under the driving of the electrostatic field, the driven deformation of the metal beam 70 in the MEMS switch of the present disclosure shown in FIG. 7 is as shown in FIG. 14. As can be seen from FIGS. 11, 12, 13 and 14, the metal beam 70 in the MEMS switch of the present disclosure may complete normal driven deformation under the driving of the bias voltage on the first drive electrode 50.

In specific implementations, in the MEMS switch provided in the embodiment of the present disclosure, as shown in FIGS. 7 and 8, the metal beam 70 may be shaped as a straight structure. Apparently, the metal beam 70 may be shaped as an arc that is convex to a side away from the base substrate 10 as shown in FIG. 15, the specific driving principle of which is the same as that in FIG. 7.

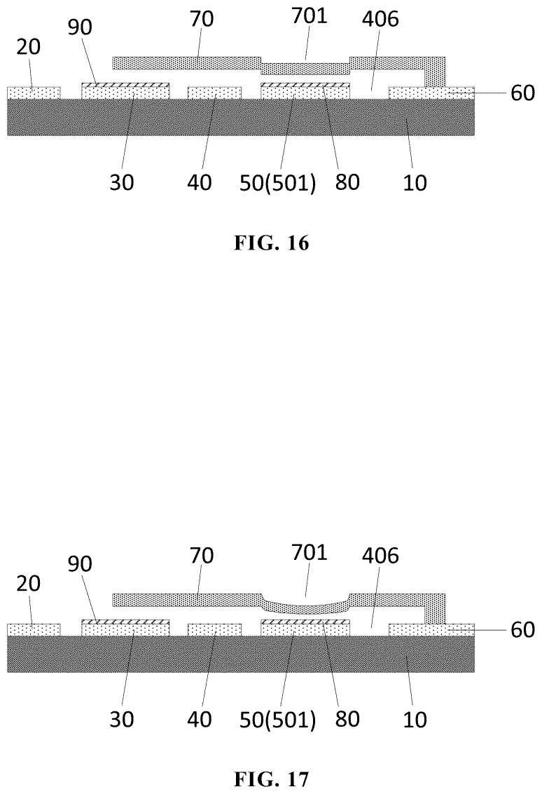

In specific implementations, in the MEMS switch provided in the embodiment of the present disclosure, as shown in FIG. 16, a first recess 701 that is recessed to the first drive electrode 50 is provided at a position of the metal beam 70 facing the first drive electrode 50. Different from FIG. 8 where the metal beam 70 is a straight structure, the metal beam 70 in FIG. 16 has a recess design at a position directly facing the first drive electrode 50, so that a distance between the metal beam 70 and the first drive electrode 50 is reduced. Therefore, the distance between the first drive electrode 50 and the metal beam 70 in FIG. 16 is shorter, resulting in a shorter moment, and to achieve the same pull-down deformation of the metal beam 70, FIG. 16 requires a lower drive voltage than that in FIG. 8. Therefore, the structural design in FIG. 16 can reduce the drive voltage of the metal beam 70, and effectively solve the problem of the increased drive voltage caused by improving the radio frequency performance of the MEMS switch in the present disclosure.

In specific implementations, in the MEMS switch provided in the embodiment of the present disclosure, as shown in FIG. 16, a bottom surface of the first recess 701 may be planar; or as shown in FIG. 17, a bottom surface of the first recess 701 may be curved. Apparently, the present disclosure is not limited thereto.

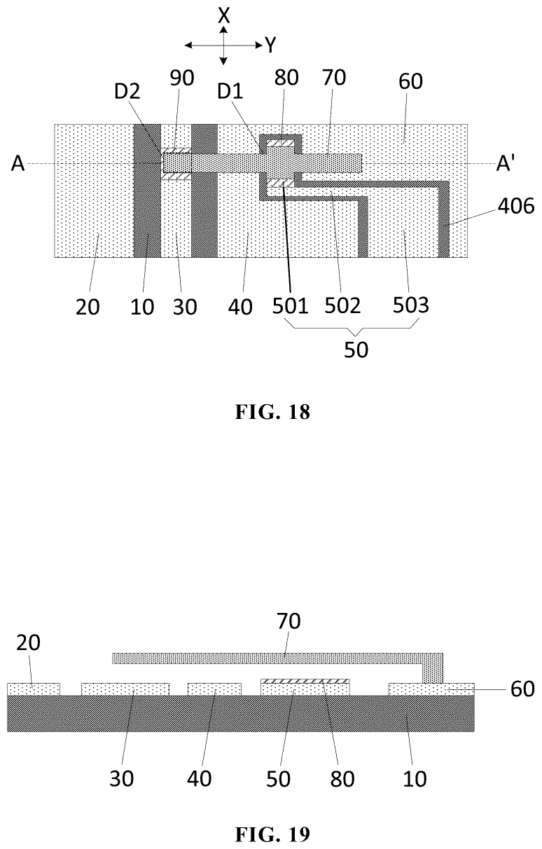

In specific implementations, in the MEMS switch provided in the embodiment of the present disclosure, as shown in FIG. 18, the position of the metal beam 70 facing first drive electrode 50 has a width greater than other positions of the metal beam 70. FIG. 18 differs from FIG. 8 in that the metal beam 70 shown in FIG. 18 is widened at the position directly facing the first drive electrode 50, so that the directly facing area, as well as the plate capacitance, between the metal beam 70 and the first drive electrode 50 is increased, which has the effect of reducing the drive voltage of the metal beam 70, and effectively solves the problem of the increased drive voltage caused by improving the radio frequency performance of the MEMS switch in the present disclosure.

In specific implementations, the MEMS switch of the present disclosure shown in FIGS. 7 to 9 has a second dielectric layer 90 provided on the signal transmission line 30, to form a capacitive switch. Apparently, in practical implementations, the second dielectric layer 90 on the signal transmission line 30 may be omitted, as shown in FIG. 19. FIG. 19 is the same as FIG. 8, except that the MEMS switch shown in FIG. 19 does not have the second dielectric layer 90 on the signal transmission line 30. Since the second dielectric layer 90 on the signal transmission line 30 is omitted in the MEMS switch in FIG. 19, when the metal beam 70 is pulled down by the drive voltage, a second end (free end) of the metal beam 70 will directly contact the signal transmission line 30, and thus, FIG. 19 shows a contact MEMS switch structure having the first drive electrode separated from the signal transmission line 30.

It should be noted that the structural designs in FIGS. 15, 16, 17, 18 and FIG. 19 in the above embodiments may be combined according to the actual situation. For example, the recess design in FIG. 16 and the widening design in FIG. 18 may be combined into the structure shown in FIG. 8, and so on.

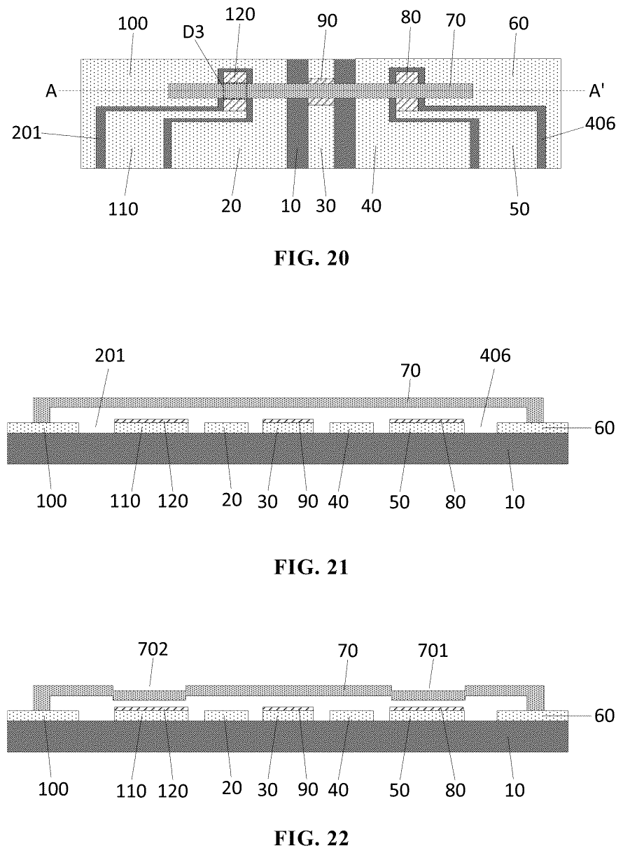

It should be noted that although the MEMS switches shown in FIGS. 8, 15, 16, 17, 18, and 19 in the above embodiments are all illustrated taking the cantilever beam structure as an example, the MEMS switch provided in the embodiments of the present disclosure may also be a structure with double end fixed, as shown in FIGS. 20 and 21. FIG. 20 is a top view of an MEMS switch having a structure with double end fixed, and FIG. 21 is a side sectional view taken along AA′ in FIG. 20. A second end of the metal beam 70 is electrically connected to the first ground electrode 20. FIG. 21 differs from FIG. 8 in that the metal beam 70 in FIG. 21 is changed to a beam structure with double end fixed, and the single-side drive electrode design is changed to a double-side drive electrode design, but the driving principle is the same.

In specific implementations, as shown in FIGS. 20 to 21, the MEMS switch provided in the embodiments of the present disclosure further includes: a fourth ground electrode 100 on a side of the first ground electrode 40 away from the second ground electrode 20, and a second drive electrode 110 between the first ground electrode 20 and the fourth ground electrode 100. A second end of the metal beam 70 is electrically connected to the fourth ground electrode 100, and the orthographic projection of the metal beam 70 on the base substrate 10 is overlapped with an orthographic projection of the second drive electrode 110 on the base substrate 10. In this manner, an MEMS switch with a double-side drive electrode design of a beam structure with double end fixed can be formed.

In specific implementations, in the MEMS switch provided in the embodiment of the present disclosure, as shown in FIGS. 20 and 21. the first ground electrode 20 and the fourth ground electrode 100 may form an integral structure, and the first ground electrode 20 and the fourth ground electrode 100 form a second hollowed-out region 201 in which the second drive electrode 110 is located. Specifically, the first ground electrode 20, the fourth ground electrode 100, and the second hollowed-out region 201 may be structures formed by patterning the first ground electrode 2 in FIG. 1 in the existing art. In other words, in the existing art, a second hollowed-out region is formed in the first ground electrode 2 in FIG. 1, in which the second drive electrode 110 is provided, so that the MEMS switch of the double-side drive electrode design is achieved based on the original ground electrode of the MEMS switch without too many additional manufacturing processes, thereby simplifying the process.

Apparently, in practical implementations, the first ground electrode 20 and the fourth ground electrode 100 may be provided as two separate ground electrodes. For example, the first ground electrode 20 may be equivalent to the first ground electrode 2 in FIG. 1, and FIG. 21 of the present disclosure may be equivalent to adding the fourth ground electrode 100 and the second drive electrode 110 to the left side of the first ground electrode 2 in FIG. 1, thereby implementing a double-side driving design of a beam structure with double end fixed.

In specific implementations, in the MEMS switch provided in the embodiment of the present disclosure, as shown in FIG. 20, the second drive electrode 110 has the same (substantially the same) shape as the second hollowed-out region 201, and the orthographic projection of the second drive electrode 110 on the base substrate 10 has an area smaller than an orthographic projection of the second hollowed-out region 201 on the base substrate 10. In this manner, it is ensured that the second drive electrode 110 is insulated from the first ground electrode 20 and the fourth ground electrode 100.

Specifically, through cooperation of the second drive electrode 110 and the first drive electrode 50 in FIG. 21, the pull-down driven deformation of the metal beam 70 is achieved, and thus regulation and control of the radio frequency signal by the MEMS switch is implemented.

In specific implementations, in the MEMS switch provided in the embodiment of the present disclosure, as shown in FIGS. 20 and 21, the second hollowed-out region 201 and the first hollowed-out region 406 may be symmetrical about the signal transmission line 30, and the second drive electrode 110 and the first drive electrode 50 may be symmetrical about the signal transmission line 30. In this manner, the manufacturing process can be conveniently unified, and the performance of the MEMS switch can be improved.

In specific implementations, as shown in FIGS. 20 to 21, the MEMS switch provided in the embodiments of the present disclosure further includes a third dielectric layer 120 on a side of the second drive electrode 110 away from the base substrate 10. An overlap region of the orthographic projections of the metal beam 70 and the second drive electrode 110 on the base substrate 10 is a third overlap region D3, and an orthographic projection of the third dielectric layer 120 on the base substrate 10 has an area greater than an orthographic projection of the third overlap region D3 on the base substrate 10. This prevents short circuit of the metal beam 70 and the second drive electrode 110 when the MEMS device is in the off state, which may affect the performance of the switch.

In specific implementations, in the MEMS switch provided in the embodiment of the present disclosure, as shown in FIG. 22, a first recess 701 that is recessed to the first drive electrode 50 is provided at a position of the metal beam 70 facing first drive electrode 50, and a second recess 702 that is recessed to the second drive electrode 110 is provided at a position of the metal beam 70 facing second drive electrode 110. Specifically, the metal beam 70 in FIG. 22 has recesses designed at a position facing the first drive electrode 50 and at a position facing the second drive electrode 110, respectively, so that a distance between the metal beam 70 and each of the first drive electrode 50 and the second drive electrode 110 is reduced. Therefore, the distance between the metal beam 70 and each of the first drive electrode 50 and the second drive electrode 110, in FIG. 22 is shorter, resulting in a shorter moment, and to achieve the same pull-down deformation of the metal beam 70, FIG. 22 requires a lower drive voltage than FIG. 21. Therefore, the structural design in FIG. 22 can reduce the drive voltage of the metal beam 70, and effectively solve the problem of the increased drive voltage caused by improving the radio frequency performance of the MEMS switch in the present disclosure.

In specific implementations, in the MEMS switch provided in the embodiment of the present disclosure, as shown in FIG. 22, a bottom surface of the second recess 702 may be planar or curved.

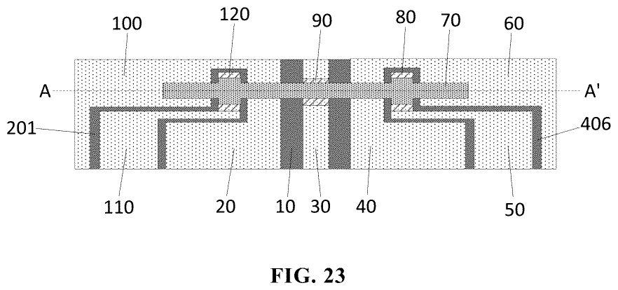

In specific implementations, in the MEMS switch provided in the embodiment of the present disclosure, as shown in FIG. 23, the position of the metal beam 70 facing the first drive electrode 50 has a width greater than other positions of the metal beam 70, and the position of the metal beam 70 facing the second drive electrode 110 has a width greater than other positions (except the position of metal beam 70 facing first drive electrode 50) of the metal beam 70. Specifically, FIG. 23 differs from FIG. 21 in that the metal beam 70 shown in FIG. 23 is widened at the position directly facing the first drive electrode 50, and at a position directly facing the second drive electrode 110, so that the directly facing area, as well as the plate capacitance, between the metal beam 70 and each of the first drive electrode 50 and the second drive electrode 110 is increased, which has the effect of reducing the drive voltage of the metal beam 70, and effectively solve the problem of the increased drive voltage caused by improving the radio frequency performance of the MEMS switch in the present disclosure.

In specific implementations, in the MEMS switch provided in the embodiment of the present disclosure, the metal beam may be made of a material including, but not limited to, Au, Ag, Cu, or Al which have a certain elasticity, and can be deformed under the action of a drive voltage to implement the function of a mechanical switch.

Optionally, the specific type of the MEMS switch in the embodiment of the present disclosure is not particularly limited, and may include, but is not limited to, a phase shifter, a reconfigurable antenna, a switch, a reconfigurable communication device based on a switch structure, and the like, and those skilled in the art may select the MEMS switch according to the actual situation.

Based on the same inventive concept, an embodiment of the present disclosure further provides an electronic device, including the MEMS switch provided in the above embodiment of the present disclosure. Since the electronic device solves the technical problem based on a principle similar to the MEMS switch, the implementation of the electronic device may be referred to that of the MEMS switch, and repeated descriptions are omitted here.

According to the MEMS switch and the electronic equipment provided in the embodiments of the present disclosure, the electrode structure is configured to include a first ground electrode, a signal transmission line, a second ground electrode, a first drive electrode and a third ground electrode which are sequentially arranged at intervals, where the first ground electrode, the signal transmission line and the second ground electrode forma coplanar waveguide (CPW) structure of the MEMS switch, and the signal transmission line for transmitting radio frequency and microwave signals is separated from the first drive electrode for loading a direct current bias voltage, so that the structural integrity of the “ground-signal-ground” CPW structure in the RF MEMS switch is guaranteed while the decoupling of the signal transmission line and the first drive electrode is implemented. The MEMS switch provided in the embodiments of the present disclosure can not only implementing decoupling of the first drive electrode and the signal transmission line to prevent the problem of crosstalk, but also ensure the radio frequency performance of the MEMS switch.

While the preferred embodiments of the present disclosure have been described, additional changes and modifications to those embodiments may occur to those skilled in the art once they learn about the basic inventive concepts. Therefore, it is intended that the appended claims should be interpreted as including the preferred embodiments and all changes and modifications that fall within the scope of the present disclosure.

It will be apparent to those skilled in the art that various changes and variations may be made to the embodiments of the present disclosure without departing from the spirit and scope of the embodiments of the present disclosure. Therefore, if such modifications and variations to the embodiments of the present disclosure are within the scope of the claims of the present disclosure and their equivalents, the present disclosure is also intended to encompass such modifications and variations.

What is claimed is:

1. An MEMS switch, comprising:
a base substrate;
an electrode structure on the base substrate, comprising a first ground electrode, a signal transmission line, a second ground electrode, a first drive electrode and a third ground electrode which are sequentially arranged on the base substrate at intervals; and
a metal beam stretching over the electrode structure, wherein a first end of the metal beam is electrically connected to the third ground electrode, an orthographic projection of a second end of the metal beam on the base substrate is within an orthographic projection of the signal transmission line on the base substrate, and an orthographic projection of the metal beam on the base substrate is overlapped with an orthographic projection of the first drive electrode on the base substrate.

2. The MEMS switch according to claim 1, wherein the second ground electrode and the third ground electrode form an integral structure, and the second ground electrode and the third ground electrode form a first hollowed-out region in which the first drive electrode is located.

3. The MEMS switch according to claim 2, wherein the first drive electrode has the same shape as the first hollowed-out region, and the orthographic projection of the first drive electrode on the base substrate has an area smaller than an orthographic projection of the first hollowed-out region on the base substrate.

4. The MEMS switch according to claim 3, wherein the first drive electrode is a continuously bent structure.

5. The MEMS switch according to claim 4, wherein the first drive electrode comprises: a first portion extending in a first direction, a second portion extending in a second direction, and a third portion extending in the first direction; and one end of the first portion is electrically connected to one end of the second portion, and the other end of the second portion is electrically connected to one end of the third portion; wherein the first direction is an extending direction of the signal transmission line, and the second direction is perpendicular to the first direction.

6. The MEMS switch according to claim 5, wherein the first drive electrode has a substantially “ [symbol] ” shape.

7. The MEMS switch according to claim 5, wherein the orthographic projection of the metal beam on the base substrate is overlapped with an orthographic projection of the first portion on the base substrate.

8. The MEMS switch according to any one of claims 1 to 7, further comprising a first dielectric layer on a side of the first drive electrode away from the base substrate, wherein an overlap region of the orthographic projections of the metal beam and the first drive electrode on the base substrate is a first overlap region, and an orthographic projection of the first dielectric layer on the base substrate has an area greater than an area of an orthographic projection of the first overlap region on the base substrate.

9. The MEMS switch according to claim 8, further comprising a second dielectric layer on a side of the signal transmission line away from the base substrate, wherein the orthographic projections of the metal beam and the signal transmission line on the base substrate have a second overlap region, and an orthographic projection of the second dielectric layer on the base substrate has an area greater than an area of an orthographic projection of the second overlap region on the base substrate.

10. The MEMS switch according to any one of claims 1 to 9, wherein the metal beam is shaped as a straight structure, or an arc that is convex to a side away from the base substrate.

11. The MEMS switch according to any one of claims 1 to 9, wherein a first recess that is recessed to the first drive electrode is provided at a position of the metal beam facing first drive electrode.

12. The MEMS switch according to claim 11, wherein a bottom surface of the first recess is planar or curved.

13. The MEMS switch according to any one of claims 1 to 12, wherein a position of the metal beam facing first drive electrode has a width greater than other positions of the metal beam.

14. The MEMS switch according to any one of claims 1 to 13, further comprising: a fourth ground electrode on a side of the first ground electrode away from the second ground electrode, and a second drive electrode between the first ground electrode and the fourth ground electrode; wherein the second end of the metal beam is electrically connected to the fourth ground electrode, the orthographic projection of the metal beam on the base substrate is overlapped with an orthographic projection of the second drive electrode on the base substrate.

15. The MEMS switch according to claim 14, wherein the first ground electrode and the fourth ground electrode form an integral structure, and the first ground electrode and the fourth ground electrode form a second hollowed-out region in which the second drive electrode is located.

16. The MEMS switch according to claim 15, wherein the second drive electrode has the same shape as the second hollowed-out region, and the orthographic projection of the second drive electrode on the base substrate has an area smaller than an area of an orthographic projection of the second hollowed-out region on the base substrate.

17. The MEMS switch according to claim 16, wherein the second drive electrode and the first drive electrode are symmetrical about the signal transmission line.

18. The MEMS switch according to claim 16 or 17, further comprising a third dielectric layer on a side of the second drive electrode away from the base substrate, wherein an overlap region of the orthographic projections of the metal beam and the second drive electrode on the base substrate is a third overlap region, and an orthographic projection of the third dielectric layer on the base substrate has an area greater than an area of an orthographic projection of the third overlap region on the base substrate.

19. The MEMS switch according to any one of claims 16 to 18, wherein a second recess that is recessed to the second drive electrode is provided at a position of the metal beam facing the second drive electrode.

20. The MEMS switch according to claim 19, wherein a bottom surface of the second recess is planar or curved.

21. The MEMS switch according to any one of claims 16 to 20, wherein a position of the metal beam facing the second drive electrode has a width greater than other positions of the metal beam.

22. The MEMS switch according to any one of claims 1 to 21, wherein the metal beam is made of a material comprising Au, Ag, Cu, or Al.

23. An electronic device, comprising the MEMS switch according to any one of claims 1 to 22.
